(19) United States
(12) Patent Application Publication
(10) Pub. No.: US 2025/0176379 A1
(43) Pub. Date: May 29, 2025

(54) DISPLAY DEVICE AND METHOD OF FABRICATING THE SAME

(71) Applicant: Samsung Display Co., LTD., Yongin-si (KR)

(72) Inventors: Min Gyu KIM, Yongin-si (KR); Jae Seob CHUNG, Yongin-si (KR); Eun Chong JOO, Yongin-si (KR)

(21) Appl. No.: 18/745,769

(22) Filed: Jun. 17, 2024

(30) Foreign Application Priority Data
Nov. 28, 2023 (KR) 10-2023-0167531

(51) Int. Cl. H10K 59/131; H10K 59/12; H10K 59/122; H10K 59/80

(52) U.S. Cl. CPC H10K 59/131; H10K 59/1201; H10K 59/122; H10K 59/80515

(57) ABSTRACT

The present disclosure relates to a display device whose defect rate can be reduced or minimized, and a method of fabricating the display device. According to one or more embodiments of the disclosure, a display device includes a first pixel including a first pixel circuit and a first light-emitting element, the first pixel circuit being separated from a portion of the first light-emitting element, and a second pixel including a second pixel circuit and a second light-emitting element, the second pixel circuit being separated from a portion of the second light-emitting element, and being connected to a portion of the first light-emitting element.

### CROSS-REFERENCE TO RELATED APPLICATION

This application claims priority to, and the benefit of, Korean Patent Application No. 10-2023-0167531, filed on Nov. 28, 2023, in the Korean Intellectual Property Office, the disclosure of which is incorporated herein in its entirety by reference.

### BACKGROUND

### 1. Field

The present disclosure relates to a display device whose defect rate can be reduced, and a method of fabricating the display device.

### 2. Description of the Related Art

An organic light-emitting display device includes a display element whose luminance is changed by a current, for example, includes an organic light-emitting diode.

Such an organic light-emitting display device includes a plurality of pixels that provide light of different colors.

### SUMMARY

Aspects of the present disclosure provide a display device whose defect rate can be reduced or minimized, and a method of fabricating the display device.

According to one or more embodiments of the disclosure, a display device includes a first pixel including a first pixel circuit and a first light-emitting element, the first pixel circuit being separated from a portion of the first light-emitting element, and a second pixel including a second pixel circuit and a second light-emitting element, the second pixel circuit being separated from a portion of the second light-emitting element, and being connected to a portion of the first light-emitting element.

A first anode of the first light-emitting element may include a first part and a second part separated from each other by a first cutting hole penetrating the first anode, wherein a second anode of the second light-emitting element includes a first part and a second part separated from each other by a second cutting hole penetrating the second anode.

The first part of the first anode may be connected to a first driving transistor of the first pixel circuit, wherein the first part of the second anode is connected to a second driving transistor of the second pixel circuit.

The second part of the first anode may be connected to a first light-emitting layer of the first light-emitting element and the first part of the second anode.

The display device may further include a connection pattern connecting the second part of the first anode to the first part of the second anode.

The connection pattern may be at a same layer as the first anode and the second anode.

The connection pattern may include conductive ink.

The conductive ink may include Ag ink.

The display device may further include a pixel-defining layer above the connection pattern to overlap the connection pattern, and defining a pixel area of the first pixel and a pixel area of the second pixel.

A gate electrode and a drain electrode of the first driving transistor of the first pixel circuit may be separated from the first pixel circuit, wherein a source electrode of the first driving transistor is separated from the first anode of the first light-emitting element.

The first driving transistor of the first pixel circuit may include an active layer including the drain electrode and the source electrode, and including a first part and a second part separated from each other by a third cutting hole penetrating the active layer.

The first part of the active layer may include the source electrode of the first driving transistor and a channel region of the first driving transistor, wherein the second part of the active layer includes the drain electrode of the first driving transistor.

The display device may further include an insulating layer above the first driving transistor, wherein the third cutting hole penetrates the insulating layer.

The display device may further include a first data line connected to the first pixel, and a second data line connected to the second pixel.

The display device may further include a data driver for transmitting a data voltage, which corresponds to the first pixel, to the second data line in a data input period of the first pixel.

The display device may further include a data converter for converting first digital video data corresponding to the second pixel into second digital video data corresponding to the first pixel, and for providing the second digital video data to the data driver, wherein the data driver is configured to generate the data voltage corresponding to the first pixel based on the second digital video data.

The data converter may include a lookup table having coordinate information of coordinates of the first pixel and coordinates of the second pixel.

The data converter may be configured to convert the first digital video data into the second digital video data based on the coordinates of the first pixel and the coordinates of the second pixel.

The first light-emitting element may include a green light-emitting layer, and
wherein the second light-emitting element includes a red light-emitting layer or a blue light-emitting layer.

The second pixel may be adjacent to the first pixel.

According to one or more embodiments of the disclosure, a method of fabricating a display device includes preparing a substrate having thereabove a first driving transistor of a first pixel, a second driving transistor of a second pixel, and a first insulating layer above the first and second driving transistors, separating a first gate electrode of the first driving transistor from a pixel circuit of the first pixel, dividing an active layer of the first driving transistor into a first part including a first channel region and a first source electrode, and a second part including a first drain electrode, by forming a first cutting hole penetrating the first insulating layer and the active layer of the first driving transistor, forming a second insulating layer above the first insulating layer, forming, above the second insulating layer, a first anode connected to the first source electrode, and a second anode connected to a second source electrode, dividing the first anode into a first part connected to the first driving transistor, and a second part to be connected to a first light-emitting layer of the first pixel, and dividing the second anode into a first part connected to the second driving transistor of the second pixel, and a second part, by forming a second cutting hole and a third cutting hole penetrating the first anode and the second anode, respectively, connecting the second part of the first anode to the first part of the second anode, forming a pixel-defining layer above the first anode and the second anode, forming the first light-emitting layer above the first anode, forming a second light-emitting layer above the second anode, and forming a cathode above the first light-emitting layer and the second light-emitting layer.

The first light-emitting layer may include a green light-emitting layer, wherein the second light-emitting layer includes a red light-emitting layer or a blue light-emitting layer.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

### BRIEF DESCRIPTION OF THE DRAWINGS

These and/or other aspects will become apparent and more readily appreciated from the following description of the embodiments, taken in conjunction with the accompanying drawings in which:

FIG. 1 is a circuit diagram of a display device according to one or more embodiments;

FIG. 2 is a diagram for explaining a method of repairing the circuit of the display device of FIG. 1;

FIG. 3 is a partial cross-sectional view of a first pixel, a second pixel, and a third pixel of FIG. 2;

FIGS. 4 through 9 are cross-sectional views for explaining a method of fabricating a display device according to one or more embodiments;

FIG. 10 is a block diagram of a driving circuit of a display device according to one or more embodiments;

FIG. 11 shows a lookup table included in a data converter of FIG. 10; and

FIG. 12 is a diagram for explaining luminance contributions of a red pixel, a green pixel, and a blue pixel of a display device.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure. The present disclosure covers all modifications, equivalents, and replacements within the idea and technical scope of the present disclosure. Further, each of the features of the various embodiments of the present disclosure may be combined with each other, in part or in whole, and technically various interlocking and driving are possible. Each embodiment may be implemented independently of each other or may be implemented together in an association.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the term “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value. Further, the use of “may” when describing embodiments of the present disclosure refers to “one or more embodiments of the present disclosure.”

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

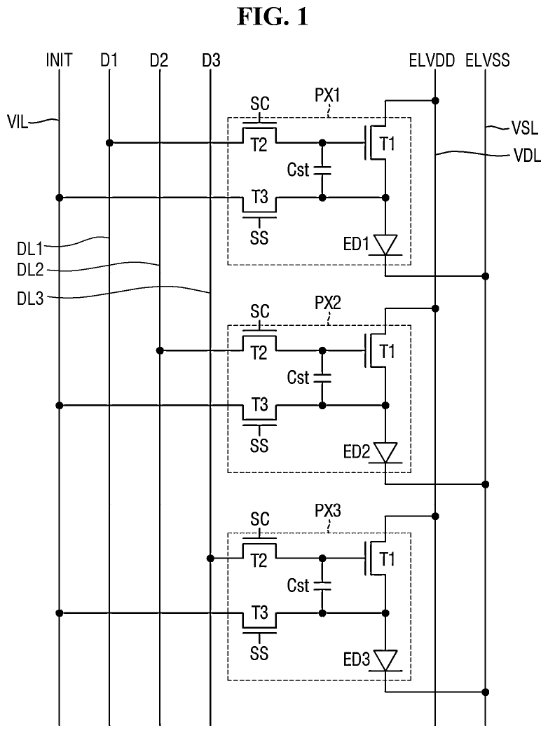

FIG. 1 is a circuit diagram of a display device according to one or more embodiments.

The display device may include a plurality of pixels. FIG. 1 illustrates three adjacent pixels PX1, PX2, and PX3 among the pixels.

As illustrated in FIG. 1, the pixels may include a first pixel PX1, a second pixel PX2, and a third pixel PX3. Each of the first pixel PX1, the second pixel PX2, and the third pixel PX3 may include a plurality of transistors T1, T2, and T3, at least one capacitor Cst, and at least one light-emitting diode, which is a light-emitting element.

For example, the first pixel PX1 may include a first light-emitting element ED1, the second pixel PX2 may include a second light-emitting element ED2, and the third pixel PX3 may include a third light-emitting element ED3. The first light-emitting element ED1, the second light-emitting element ED2, and the third light-emitting element ED3 may provide light of different respective colors. For example, the first light-emitting element ED1 may include a light-emitting layer that provides red light, the second light-emitting element ED2 may include a light-emitting layer that provides green light, and the third light-emitting element ED3 may include a light-emitting layer that provides blue light.

The first pixel PX1, the second pixel PX2, and the third pixel PX3 may have the same configuration. Therefore, the configuration of the first pixel PX1 will be described below as a representative example.

The first pixel PX1 may include a pixel circuit, and a light-emitting element connected to the pixel circuit. Here, the pixel circuit of the first pixel PX1 may include, for example, a driving transistor T1, a switching transistor T2, an initialization transistor T3, and a capacitor Cst.

A drain electrode and a source electrode of each transistor T1, T2 or T3, which will be described below, are termed as such to distinguish two electrodes located on respective sides of a channel of each transistor T1, T2 or T3. Depending on a potential difference, the source electrode can be changed to the drain electrode, or the drain electrode can be changed to the source electrode.

A gate electrode of the driving transistor T1 may be connected to a first electrode of the capacitor Cst, a drain electrode of the driving transistor T1 may be connected to a driving voltage line VDL that transmits a driving voltage ELVDD, and a source electrode of the driving transistor T1 may be connected to an anode of the light-emitting element ED1 and to a second electrode of the capacitor Cst. The driving transistor T1 may receive a data voltage D1, D2, or D3 according to a switching operation of the switching transistor T2, and may supply a driving current to the light-emitting element ED1 according to a voltage stored in the capacitor Cst.

A gate electrode of the switching transistor T2 may be connected to a first scan line that transmits a first scan signal SC, a drain electrode of the switching transistor T2 may be connected to a data line that transmits a data voltage D1, D2, or D3 or a reference voltage, and a source electrode of the switching transistor T2 may be connected to the first electrode of the capacitor Cst and to the gate electrode of the driving transistor T1. A plurality of data lines DL1, DL2, and DL3 may respectively transmit different data voltages D1, D2, and D3. The switching transistors T2 of the pixels PX1, PX2, and PX3 may be respectively connected to different data lines DL1, DL2, and DL3. For example, the switching transistor T2 of the first pixel PX1 may be connected to a first data line DL1, the switching transistor T2 of the second pixel PX2 may be connected to a second data line DL2, and the switching transistor T2 of the third pixel PX3 may be connected to a third data line DL3.

The switching transistor T2 may be turned on according to the first scan signal SC to transmit the reference voltage or the data voltage D1, D2, or D3 to the gate electrode of the driving transistor T1 and to the first electrode of the capacitor Cst.

A gate electrode of the initialization transistor T3 may be connected to a second scan line that transmits a second scan signal SS, a drain electrode of the initialization transistor T3 may be connected to the second electrode of the capacitor Cst, to the source electrode of the driving transistor T1, and to the anode of the light-emitting element ED1, and a source electrode of the initialization transistor T3 may be connected to an initialization voltage line VIL that transmits an initialization voltage INIT. The initialization transistor T3 may be turned on according to the second scan signal SS to transmit the initialization voltage INIT to the anode of the light-emitting element ED1 and to the second electrode of the capacitor Cst, thereby initializing the voltage of the anode of the light-emitting element ED1.

The first electrode of the capacitor Cst is connected to the gate electrode of the driving transistor T1, and the second electrode of the capacitor Cst is connected to the drain electrode of the initialization transistor T3 and to the anode of the light-emitting element ED1. A cathode CE of the light-emitting element ED1 is connected to a common voltage line VSL that transmits a common voltage ELVSS.

The light-emitting element ED1 may emit light at a luminance level corresponding to a driving current generated by the driving transistor T1.

An example of the operation of the circuit illustrated in FIG. 1 (e.g., an example of the operation during one frame) will be described as follows. Here, a case where the transistors T1, T2, and T3 are N-type channel transistors will be described as an example, but the present disclosure is not limited to this case.

If one frame starts, the first scan signal SC at a high level and the second scan signal SS at a high level may be supplied during an initialization period to turn on the switching transistor T2 and the initialization transistor T3. A reference voltage from a data line may be supplied to the gate electrode of the driving transistor T1 and to one end of the capacitor Cst through the turned-on switching transistor T2, and the initialization voltage INIT may be supplied to the source electrode of the driving transistor T1 and to the anode of the light-emitting element ED1 through the turned-on initialization transistor T3. Accordingly, during the initialization period, the source electrode of the driving transistor T1 and the anode of the light-emitting element ED1 may be initialized to the initialization voltage INIT. At this time, a difference voltage between the reference voltage and the initialization voltage INIT may be stored in the capacitor Cst.

Next, if the second scan signal SS becomes a low level while the first scan signal SC is maintained at a high level during a sensing period, the switching transistor T2 may remain on, and the initialization transistor T3 may be turned off. The gate electrode of the driving transistor T1 and the end of the capacitor Cst may be maintained at the reference voltage through the turned-on switching transistor T2, and the source electrode of the driving transistor T1 and the anode of the light-emitting element ED1 may be electrically separated from the initialization voltage line VIL through the turned-off initialization transistor T3. Accordingly, the driving transistor T1 may be turned off if the voltage of the source electrode becomes the “reference voltage-Vth” in response to a current flowing from the drain electrode to the source electrode. Vth represents a threshold voltage of the driving transistor T1. At this time, a voltage difference between the gate electrode and the source electrode of the driving transistor T1 may be stored in the capacitor Cst, and sensing the threshold voltage Vth of the driving transistor T1 may be completed. Because a data signal compensated based on characteristics information sensed during the sensing period is generated, a difference in characteristics of the driving transistor T1 between pixels can be externally compensated.

Next, if the first scan signal SC at a high level and the second scan signal SS at a low level are supplied in a data input period, the switching transistor T2 may be turned on, and the initialization transistor T3 may be turned off. A data voltage D1, D2, or D3 from each data line DL1, DL2, or DL3 is supplied to the gate electrode of the driving transistor T1 and the end of the capacitor Cst through the turned-on switching transistor T2 of each pixel PX1, PX2 or PX3. At this time, the source electrode of the driving transistor T1 and the anode of the light-emitting element ED1 may substantially maintain the potential in the sensing period due to the turned-off driving transistor T1.

Next, in an emission period, the driving transistor T1 turned on by the data voltage D1, D2, or D3 applied to the gate electrode may generate a driving current according to the data voltage D1, D2, or D3, and the light-emitting element ED1 may emit light in response to the driving current.

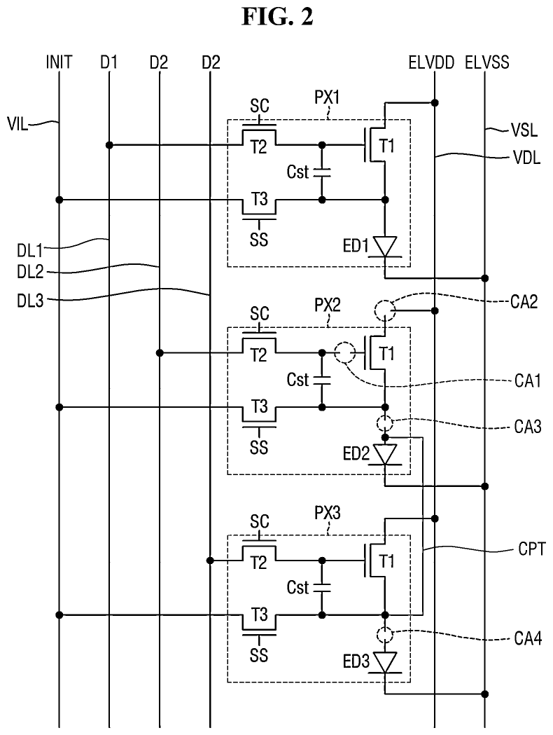

FIG. 2 is a diagram for explaining a method of repairing the circuit of the display device of FIG. 1.

As illustrated in FIG. 2, if an error occurs in at least one of the transistors (e.g., the driving transistor T1) of the second pixel PX2, the second pixel PX2 may be determined to be a defective pixel that cannot provide light normally. In this case, a repair process may be performed on the second pixel PX2. The repair process will be described in detail as follows.

First, for ease of description, the driving transistor T1, the switching transistor T2, the initialization transistor T3, and the capacitor Cst included in the first pixel PX1 will be defined as a first driving transistor T1, a first switching transistor T2, a first initialization transistor T3, and a first capacitor Cst, respectively. The driving transistor T1, the switching transistor T2, the initialization transistor T3, and the capacitor Cst included in the second pixel PX2 will be defined as a second driving transistor T1, a second switching transistor T2, a second initialization transistor T3, and a second capacitor Cst, respectively. The driving transistor T1, the switching transistor T2, the initialization transistor T3, and the capacitor Cst included in the third pixel PX3 will be defined as a third driving transistor T1, a third switching transistor T2, a third initialization transistor T3, and a third capacitor Cst, respectively.

As illustrated in FIG. 2, a gate electrode of the second driving transistor T1 may be separated from a pixel circuit of the second pixel PX2. For example, the gate electrode of the second driving transistor T1 may be cut in a first cutting area CA1. Accordingly, the gate electrode of the second driving transistor T1 may be separated from a source electrode of the second switching transistor T2 and from a first electrode of the second capacitor Cst.

As illustrated in FIG. 2, a drain electrode of the second driving transistor T1 may be separated from the pixel circuit of the second pixel PX2. For example, the drain electrode of the second driving transistor T1 may be cut in a second cutting area CA2. Accordingly, the drain electrode of the second driving transistor T1 may be separated from the driving voltage line VDL.

As illustrated in FIG. 2, an anode of the second light-emitting element ED2 may be separated from the pixel circuit of the second pixel PX2. For example, the anode of the second light-emitting element ED2 may be cut in a third cutting area CA3. Accordingly, the anode of the second light-emitting element ED2 may be separated from a source electrode of the second driving transistor T1, from a drain electrode of the second initialization transistor T3, and from a second electrode of the second capacitor Cst.

As illustrated in FIG. 2, an anode of the third light-emitting element ED3 may be separated from a pixel circuit of the third pixel PX3. For example, the anode of the third light-emitting element ED3 may be cut in a fourth cutting area CA4. Accordingly, the anode of the third light-emitting element ED3 may be separated from a source electrode of the third driving transistor T1, from a drain electrode of the third initialization transistor T3, and from a second electrode of the third capacitor Cst. Accordingly, the third pixel PX3 may be darkened.

As illustrated in FIG. 2, the source electrode of the third driving transistor T1, the drain electrode of the third initialization transistor T3, the second electrode of the third capacitor Cst, and the anode of the second light-emitting element ED2 may be connected to each other by a connection pattern CPT. In other words, the pixel circuit of the third pixel PX3, which is a normal pixel, may be connected to the second light-emitting element ED2 of the second pixel PX2, which is a defective pixel.

Through the above repair process and darkening process, the second light-emitting element ED2 of the second pixel PX2, which is a defective pixel, can be driven normally by another pixel (e.g., the third pixel PX3) that is adjacent to the second pixel PX2. For example, the second light-emitting element ED2 of the second pixel PX2 may emit light in response to a driving current generated through the pixel circuit of the third pixel PX3 (e.g., the third driving transistor T1, the third switching transistor T2, the third initialization transistor T3, and the third capacitor Cst). At this time, a second data voltage D2 rather than a third data voltage D3 corresponding to the third pixel PX3 may be applied to the third data line DL3 connected to the third pixel PX3. For example, the second data voltage D2 may be applied to the third data line DL3 in the data input period of the second pixel PX2. Therefore, the second light-emitting element ED2 of the second pixel PX2 can provide light corresponding to the magnitude (or grayscale value) of the second data voltage D2, which is the original (e.g., intended) data voltage.

Instead of the pixel circuit of the third pixel PX3, the pixel circuit of another pixel (e.g., the first pixel PX1 adjacent to the second pixel PX2) may also, or instead, be connected to the second light-emitting element ED2 of the second pixel PX2, which is a defective pixel. At this time, the first light-emitting element ED1 of another pixel (e.g., the first pixel PX1), like the third light-emitting element ED3 of the third pixel PX3 in FIG. 2, may be separated from the pixel circuit of the first pixel PX1. In addition, the pixel circuit of the first pixel PX1 may be connected to the anode of the second light-emitting element ED2. In this case, the second data voltage D2 may be applied to the first data line DL1 connected to the first pixel PX1. For example, the second data voltage D2 may be applied to the first data line DL1 in the data input period of the second pixel PX2.

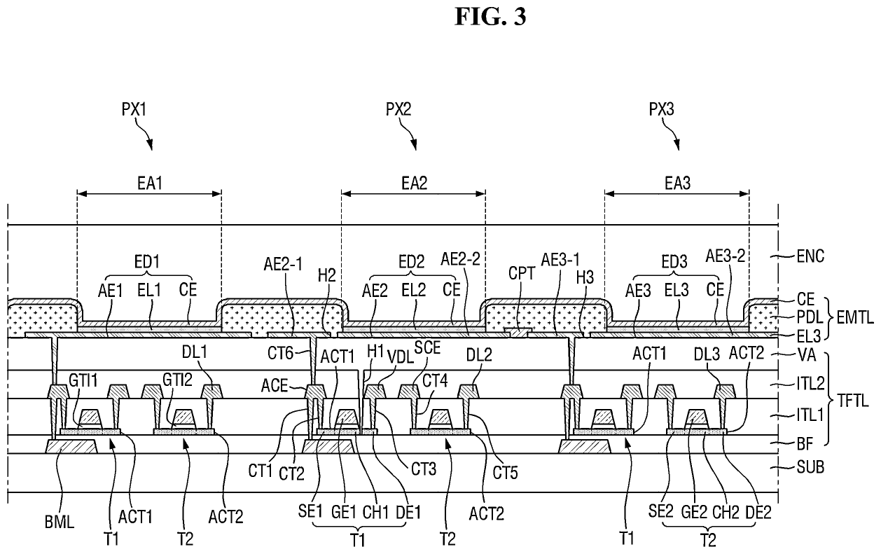

FIG. 3 is a partial cross-sectional view of the first pixel PX1, the second pixel PX2, and the third pixel PX3 of FIG. 2.

As illustrated in FIG. 3, the display device 10 may include a substrate SUB, a barrier layer BR, a thin-film transistor layer TFTL, a light-emitting element layer EMTL, and an encapsulation layer ENC. The barrier layer BR, the thin-film transistor layer TFTL, the light-emitting element layer EMTL, and the encapsulation layer ENC may be sequentially located on the substrate SUB. Here, the thin-film transistor layer TFTL may include the pixel circuit of each pixel described above.

The substrate SUB may be a rigid substrate or a flexible substrate that can be bent, folded, or rolled. The substrate SUB may be made of an insulating material such as glass, quartz, or polymer resin. The polymer material may be, for example, polyethersulphone (PES), polyacrylate (PA), polyarylate (PAR), polyetherimide (PEI), polyethylene naphthalate (PEN), polyethylene terepthalate (PET), polyphenylene sulfide (PPS), polyallylate, polyimide (PI), polycarbonate (PC), cellulose triacetate (CAT), cellulose acetate propionate (CAP), or a combination thereof. Alternatively, the substrate SUB may include a metal material.

A plurality of light-blocking layers BML may be located on the substrate SUB. The light-blocking layers BML may be made of, for example, a metal material, such as chromium (Cr) or molybdenum (Mo), or may be made of black ink or black dye. If the light-blocking layers BML are made of a metal material, they may receive static power. Accordingly, the light-blocking layers BML might not float electrically, and the electrical characteristics of transistors on the light-blocking layers BML may be stabilized. Therefore, for example, performance degradation of oxide-based transistors T1 can be reduced or minimized. Meanwhile, oxide semiconductors are sensitive to light, and changes in current amount may occur due to external light.

A buffer layer BF may be located on the light-blocking layers BML. The buffer layer BF may be located on (e.g., over) the entire surface of the substrate SUB including the barrier layer BR. The buffer layer BF may be a layer for protecting transistors T1, T2, and T3 of the thin-film transistor layer TFTL and light-emitting layers of the light-emitting element layer EMTL from moisture introduced through the substrate SUB, which is vulnerable to moisture penetration. The buffer layer BF may be composed of a plurality of inorganic layers stacked alternately. For example, the buffer layer BF may be a multilayer in which one or more inorganic layers selected from a silicon nitride layer, a silicon oxynitride layer, a silicon oxide layer, a titanium oxide layer, and an aluminum oxide layer are alternately stacked.

First active layers ACT1 and second active layers ACT2 may be located on the buffer layer BF. Each of the first active layers ACT1 may include a first drain electrode DE1, a first source electrode SE1, and a first channel region CH1. The first channel region CH1 may be located between the first drain electrode DE1 and the first source electrode SE1. Here, each of the first active layers ACT1 may be located on the buffer layer BF such that the first channel region CH1 of the first active layer ACT1 overlaps a light-blocking layer BML. Each of the second active layers ACT2 may include a second drain electrode DE2, a second source electrode SE2, and a second channel region CH2. The second channel region CH2 may be located between the second drain electrode DE2 and the second source electrode SE2.

The first active layers ACT1 may include polycrystalline silicon, monocrystalline silicon, low-temperature polycrystalline silicon, amorphous silicon, or an oxide semiconductor material. If the first active layers ACT1 include an oxide semiconductor material, they may include indium-gallium-zinc-oxide (IGZO). If the first active layers ACT1 include polycrystalline silicon or an oxide semiconductor material, then a source electrode and a drain electrode in each of the first active layers ACT1 may be conductive regions doped with ions to have conductivity. The second active layers ACT2 may be made of the same material as the first active layers ACT1 described above.

First gate-insulating layers GTI1 and second gate-insulating layers GTI2 may be located on the first active layers ACT1 and the second active layers ACT2, respectively. For example, the first gate-insulating layers GTI1 may be located on the first active layers ACT1 to overlap the first channel regions CH1 of the first active layers ACT1, and the second gate-insulating layers GTI2 may be located on the second active layers ACT2 to overlap the second channel regions CH2 of the second active layers ACT2.

First gate electrodes GE1 may be located on the first gate-insulating layers GTI1. The first gate electrodes GE1 may be located on the first gate-insulating layers GTI1 to overlap the first channel regions CH1 of the first active layers ACT1.

Second gate electrodes GE2 may be located on the second gate-insulating layers GTI2. The second gate electrodes GE2 may be located on the second gate-insulating layers GTI2 to overlap the second channel regions CH2 of the second active layers ACT2.

A first interlayer insulating layer ITL1 may be located on the first gate electrodes GE1 and on the second gate electrodes GE2. For example, the first interlayer insulating layer ITL1 may be located on (e.g., over) the entire surface of the substrate SUB including the first gate electrodes GE1 and the second gate electrodes GE2. The first interlayer insulating layer ITL1 may include an inorganic layer, for example, a silicon nitride layer, a silicon oxynitride layer, a silicon oxide layer, a titanium oxide layer, or an aluminum oxide layer. The first interlayer insulating layer ITL1 may include a plurality of inorganic layers.

A plurality of anode connection electrodes ACE, the driving voltage line VDL, a plurality of source connection electrodes SCE, the first data line DL1, the second data line DL2, and the third data line DL3 may be located on the first interlayer insulating layer ITL1.

The anode connection electrodes ACE may be respectively connected to the light-blocking layers BML through first contact holes CT1 penetrating the first interlayer insulating layer ITL1 and the buffer layer BF. In addition, the anode connection electrodes ACE may be connected to the first source electrodes SE1 of the first active layers ACT1 through second contact holes CT2 penetrating the first interlayer insulating layer ITL1. For example, the anode connection electrode ACE of the first pixel PX1 may be connected to the light-blocking layer BML of the first pixel PX1 and to the first source electrode SE1 of the first active layer ACT1 of the first pixel PX1. The anode connection electrode ACE of the second pixel PX2 may be connected to the light-blocking layer BML of the second pixel PX2 and to the first source electrode SE1 of the first active layer ACT1 of the second pixel PX2. The anode connection electrode ACE of the third pixel PX3 may be connected to the light-blocking layer BML of the third pixel PX3 and to the first source electrode SE1 of the first active layer ACT1 of the third pixel PX3.

The driving voltage line VDL may be connected to the first drain electrodes DE1 of the second active layers ACT2 through third contact holes CT3 penetrating the first interlayer insulating layer ITL1.

The source connection electrodes SCE may be connected to the second source electrodes SE2 of the second active layers ACT2 through fourth contact holes CT4 penetrating the first interlayer insulating layer ITL1. For example, the source connection electrode SCE of the first pixel PX1 may be connected to the second source electrode SE2 of the second active layer ACT2 of the first pixel PX1, the source connection electrode SCE of the second pixel PX2 may be connected to the second source electrode SE2 of the second active layer ACT2 of the second pixel PX2, and the source connection electrode SCE of the third pixel PX3 may be connected to the second source electrode SE2 of the second active layer ACT2 of the third pixel PX3.

The first data line DL1 may be connected to the second drain electrode DE2 of the first switching transistor T2 through a fifth contact hole CT5 penetrating the first interlayer insulating layer ITL1. The second data line DL2 may be connected to the second drain electrode DE2 of the second switching transistor T2 through a fifth contact hole CT5 penetrating the first interlayer insulating layer ITL1. The third data line DL3 may be connected to the second drain electrode DE2 of the third switching transistor T2 through a fifth contact hole CT5 penetrating the first interlayer insulating layer ITL1.

A second interlayer insulating layer ITL2 may be located on the anode connection electrodes ACE, the driving voltage line VDL, the source connection electrodes SCE, the first data line DL1, the second data line DL2, and the third data line DL3. For example, the second interlayer insulating layer ITL2 may be located on (e.g., over) the entire surface of the substrate SUB including the anode connection electrodes ACE, the driving voltage line VDL, the source connection electrodes SCE, the first data line DL1, the second data line DL2, and the third data line DL3. The second interlayer insulating layer ITL2 may include the same material as the first interlayer insulating layer ITL1 described above.

A planarization layer VA may be located on the second interlayer insulating layer ITL2. The planarization layer VA may be located on (e.g., over) the entire surface of the substrate SUB including the second interlayer insulating layer ITL2. The planarization layer VA may include an organic layer, such as acryl resin, epoxy resin, phenolic resin, polyamide resin, or polyimide resin.

The light-emitting element layer EMTL may be located on the planarization layer VA. For example, a first anode AE1, a second anode AE2, and a third anode AE3 may be located on the planarization layer VA. The first anode AE1 may be connected to the anode connection electrode ACE of the first pixel PX1 through a sixth contact hole CT6 penetrating the planarization layer VA and the second interlayer insulating layer ITL2. The second anode AE2 may be connected to the anode connection electrode ACE of the second pixel PX2 through a sixth contact hole CT6 penetrating the planarization layer VA and the second interlayer insulating layer ITL2. The third anode AE3 may be connected to the anode connection electrode ACE of the third pixel PX3 through a sixth contact hole CT6 penetrating the planarization layer VA and the second interlayer insulating layer ITL2.

The light-emitting element layer EMTL described above may further include a plurality of light-emitting elements and a pixel-defining layer PDL in addition to the first through third anodes AE1, AE2, and AE3 described above.

The light-emitting elements may include, for example, the first light-emitting element ED1 of the first pixel PX1, the second light-emitting element ED2 of the second pixel PX2, and the third light-emitting element ED3 of the third pixel PX3. The first light-emitting element ED1 may include the first anode AE1, a first light-emitting layer EL1, and a common electrode/cathode CE. The second light-emitting element ED2 may include the second anode AE2, a second light-emitting layer EL2, and the cathode CE. The third light-emitting element ED3 may include the third anode AE3, a third light-emitting layer EL3, and the cathode CE. The first light-emitting element ED1 may provide light through a first emission area EA1, the second light-emitting element ED2 may provide light through a second emission area EA2, and the third light-emitting element ED3 may provide light through a third emission area EA3.

The first light-emitting element ED1 may include the first anode AE1, the first light-emitting layer EL1, and the cathode CE. The first emission area EA1 may be an area where the first anode AE1, the first light-emitting layer EL1, and the cathode CE are sequentially stacked so that holes from the first anode AE1 and electrons from the cathode CE are combined with each other in the first light-emitting layer EL1 to emit light.

The second light-emitting element ED2 may include the second anode AE2, the second light-emitting layer EL2, and the cathode CE. The second emission area EA2 may be an area where the second anode AE2, the second light-emitting layer EL2, and the cathode CE are sequentially stacked so that holes from the second anode AE2 and electrons from the cathode CE are combined with each other in the second light-emitting layer EL2 to emit light.

The third light-emitting element ED3 may include the third anode AE3, the third light-emitting layer EL3, and the cathode CE. The third emission area EA3 may be an area where the third anode AE3, the third light-emitting layer EL3, and the cathode CE are sequentially stacked so that holes from the third anode AE3 and electrons from the cathode CE are combined with each other in the third light-emitting layer EL3 to emit light.

In a top emission structure in which light is emitted in a direction from a light-emitting layer (e.g., EL1) toward the cathode CE, an anode (e.g., AE1) may be formed as a single layer of molybdenum (Mo), titanium (Ti), copper (Cu) or aluminum (AI) or, to increase reflectivity, may be formed as a stacked structure (Ti/Al/Ti) of aluminum and titanium, a stacked structure (ITO/AI/ITO) of aluminum and indium tin oxide, an APC alloy, or a stacked structure (ITO/APC/ITO) of an APC alloy and indium tin oxide. The APC alloy is an alloy of silver (Ag), palladium (Pd), and copper (Cu).

The pixel-defining layer PDL defines the first through third emission areas EA1, EA2, and EA3 of the first through third pixels PX1, PX2, and PX3. To this end, the pixel-defining layer PDL may be located on the planarization layer VA to expose a portion of the first anode AE1, a portion of the second anode AE2, and a portion of the third anode AE3. The pixel-defining layer PDL may cover edges of the first anode AE1, edges of the second anode AE2, and edges of the third anode AE3. The pixel-defining layer PDL may be made of an organic layer, such as acryl resin, epoxy resin, phenolic resin, polyamide resin, or polyimide resin.

In one or more embodiments, a spacer may be located on the pixel-defining layer PDL. The spacer may support a mask during a process of manufacturing the first through third light-emitting layers EL1, EL2, and EL3. The spacer may be made of an organic layer, such as acryl resin, epoxy resin, phenolic resin, polyamide resin, or polyimide resin.

The light-emitting layers EL1, EL2, and EL3 may be formed on the anodes AE1, AE2, and AE3, respectively. The first light-emitting layer EL1 may include an organic material to emit light of a corresponding color (e.g., predetermined color). For example, the first light-emitting layer EL1 may include a hole-transporting layer, an organic material layer, and an electron-transporting layer. The organic material layer may include a host and a dopant. The organic material layer may include a material that emits light, and may be formed using a phosphorescent material or a fluorescent material.

For example, the organic material layer of the first light-emitting layer EL1 of the first emission area EA1 for emitting light of a first color (e.g., red) may be a phosphorescent material that includes a host material including carbazole biphenyl (CBP) or 1,3-bis(carbazol-9-yl) (mCP) and a dopant including any one or more of bis(1-phenylisoquinoline) acetylacetonate iridium (PIQIr(acac)), bis(1-phenylquinoline) acetylacetonate iridium (PQIr(acac)), tris (1-phenylquinoline) iridium (PQIr), or octaethylporphyrin platinum (PtOEP). Alternatively, the organic material layer of the first light-emitting layer EL1 of the first emission area EA1 may be a fluorescent material including PBD:Eu(DBM)3(Phen) or perylene. However, the present disclosure is not limited thereto.

The organic material layer of the second light-emitting layer EL2 of the second emission area EA2 for emitting light of a second color (e.g., green) may be a phosphorescent material that includes a host material including CBP or mCP and a dopant material including Ir(ppy)3(fac tris(2-phenylpyridine)iridium). Alternatively, the organic material layer of the second light-emitting layer EL2 of the second emission area EA2 for emitting light of the second color may be a fluorescent material including tris(8-hydroxyquinolino)aluminum (Alq3). However, the present disclosure is not limited thereto.

The organic material layer of the third light-emitting layer EL3 of the third emission area EA3 for emitting light of a third color (e.g., blue) may be a phosphorescent material that includes a host material including CBP or mCP and a dopant material including (4,6-F2ppy)2Irpic or L2BD111. However, the present disclosure is not limited thereto.

The cathode CE may be located on the first through third light-emitting layers EL1, EL2, and EL3. The cathode CE may cover the first through third light-emitting layers EL1, EL2, and EL3. The cathode CE may be a common layer commonly located on the first through third light-emitting layers EL1, EL2, and EL3. In one or more embodiments, a capping layer may be formed on the cathode CE.

In the top emission structure, the cathode CE may be made of a transparent conductive material (TCO) that can transmit light, such as indium tin oxide (ITO) or indium zinc oxide (IZO), or a semi-transmissive conductive material, such as magnesium (Mg), silver (Ag) or an alloy of Mg and Ag. If the cathode CE is made of a semi-transmissive conductive material, light output efficiency may be increased by a microcavity.

The encapsulation layer ENC may be formed on the light-emitting element layer EMTL. The encapsulation layer ENC may include at least one inorganic layer to reduce or prevent penetration of oxygen or moisture into the light-emitting element layer EMTL. In addition, the encapsulation layer ENC may include at least one organic layer to protect the light-emitting element layer EMTL from foreign substances, such as dust. For example, the encapsulation layer ENC may include a first encapsulating inorganic layer, an encapsulating organic layer, and a second encapsulating inorganic layer sequentially stacked on the cathode CE.

The first encapsulating inorganic layer of the encapsulation layer ENC may be located on the cathode CE, the encapsulating organic layer may be located on the first encapsulating inorganic layer, and the second encapsulating inorganic layer may be located on the encapsulating organic layer. Each of the first encapsulating inorganic layer and the second encapsulating inorganic layer may be a multilayer in which one or more inorganic layers selected from a silicon nitride layer, a silicon oxynitride layer, a silicon oxide layer, a titanium oxide layer, and an aluminum oxide layer are alternately stacked. The encapsulating organic layer may be an organic layer, such as acryl resin, epoxy resin, phenolic resin, polyamide resin, or polyimide resin.

A portion of the first active layer ACT1 included in the second pixel PX2 may be cut. For example, the first drain electrode DE1 of the second driving transistor T1 may be cut in the second cutting area CA2. To this end, a first cutting hole H1 penetrating the second interlayer insulating layer ITL2, the first interlayer insulating layer ITL1, and the first active layer ACT1 of the second pixel PX2 may be formed in the second cutting area CA2. For example, the first active layer ACT1 of the second pixel PX2 may be cut in the second cutting area CA2 (e.g., an area between the first channel region CH1 and the first drain electrode DE1) into two parts. In an example, the first active layer ACT1 of the second pixel PX2 may be divided into a first part (e.g., a first part including the first source electrode SE1 and the first channel region CH1) and a second part (e.g., a second part including the first drain electrode DE1). Accordingly, the connection between the first drain electrode DE1 of the second driving transistor T1 and the driving voltage line VDL may be broken by the first cutting hole H1 of the second cutting area CA2.

A portion of the second anode AE2 included in the second pixel PX2 may be cut. For example, the second anode AE2 may be cut in the third cutting area CA3. To this end, a second cutting hole H2 penetrating the second anode AE2 may be formed in the third cutting area CA3. For example, the second anode AE2 may be cut in the third cutting area CA3 into two parts. In an example, the second anode AE2 may be divided into a first part AE2-1 (e.g., a first part connected to the second anode connection electrode ACE of the second pixel PX2 and not connected to the second light-emitting layer EL2), and a second part AE2-2 (e.g., a second part not connected to the second anode connection electrode ACE of the second pixel PX2 and connected to the second light-emitting layer EL2). Accordingly, the connection between the second part AE2-2 of the second anode AE2 and the anode connection electrode ACE of the second pixel PX2 may be broken by the second cutting hole H2 of the third cutting area CA3. Here, the first part AE2-1 of the second anode AE2 and the third cutting area CA3 may overlap the pixel-defining layer PDL. In addition, edges of the second part AE2-2 of the second anode AE2 may overlap the pixel-defining layer PDL, and the rest of the second part AE2-2 may be located in the second emission area EA2 and connected to the second light-emitting layer EL2.

In one or more embodiments, the first gate electrode GE1 of the second driving transistor T1 may be separated from the first electrode of the second capacitor Cst and from the second source electrode SE2 of the second switching transistor T2 by another cutting hole (e.g., a cutting hole of the first cutting area CA1).

Accordingly, the second driving transistor T1 and the second light-emitting element ED2 of the second pixel PX2 may be electrically and/or physically separated from the pixel circuit of the second pixel PX2.

A portion of the third anode AE3 included in the third pixel PX3 may be cut. For example, the third anode AE3 may be cut in the fourth cutting area CA4. To this end, a third cutting hole H3 penetrating the third anode AE3 may be formed in the fourth cutting area CA4. For example, the third anode AE3 may be cut in the fourth cut area CA4 into two parts. In an example, the third anode AE3 may be divided into a first part AE3-1 (e.g., a first part connected to the third anode connection electrode ACE of the third pixel PX3, and not connected to the third light-emitting layer EL3) and a second part AE3-2 (e.g., a second part not connected to the third anode connection electrode ACE of the third pixel PX3, and connected to the third light-emitting layer EL3). Accordingly, the connection between the second part AE3-2 of the third anode AE3 and the anode connection electrode ACE of the third pixel PX3 may be broken by the third cutting hole H3 of the fourth cutting area CA4. Here, the first part AE3-1 of the third anode AE3 and the fourth cutting area CA4 may overlap the pixel-defining layer PDL. In addition, edges of the second part AE3-2 of the third anode AE3 may overlap the pixel-defining layer PDL, and the rest of the second part AE3-2 may be located in the third emission area EA3.

Accordingly, the third light-emitting element ED3 of the third pixel PX3 may be electrically and/or physically separated from the pixel circuit of the third pixel PX3.

The second part AE2-2 of the second anode AE2 and the first part AE3-1 of the third anode AE3 may be connected to each other. For example, the second part AE2-2 of the second anode AE2 and the first part AE3-1 of the third anode AE3 may be connected to each other by the connection pattern CPT. The connection pattern CPT may be located on the same layer as the first through third anodes AE1, AE2, and AE3. For example, the connection pattern CPT may be located on the planarization layer VA. At least a portion of the connection pattern CPT may contact the first part AE2-1 of the second anode AE2, the second part AE3-2 of the third anode AE3, and the planarization layer VA. At least a portion of the connection pattern CPT may be located on the first part AE2-1 of the second anode AE2 and on the second part AE3-2 of the third anode AE3. At least a portion of the connection pattern CPT may be located between the planarization layer VA and the pixel-defining layer PDL. At least a portion of the connection pattern CPT may be located between the second part AE2-2 of the second anode AE2 and the pixel-defining layer PDL. At least a portion of the connection pattern CPT may be located between the first part AE3-1 of the third anode AE3 and the pixel-defining layer PDL. The connection pattern CPT may include, for example, conductive ink. The conductive ink may include, for example, Ag ink. The Ag ink may include Ag nanoparticles dispersed in the ink.

The pixel circuit of the third pixel PX3 may be connected to the second anode AE2 of the second pixel PX2, and not connected to the third anode AE3 of the third pixel PX3, by the third cutting hole H3 and the connection pattern CPT. In other words, the pixel circuit of the third pixel PX3 including the third driving transistor T1, the third switching transistor T2, the third initialization transistor T3, and the third capacitor Cst may be connected to the second light-emitting element ED2 of the second pixel PX2 instead of the third light-emitting element ED3 of the third pixel PX3. Accordingly, the second light-emitting element ED2 of the second pixel PX2, which is a defective pixel, can be driven by the pixel circuit of the third pixel PX3, which is a normal pixel.

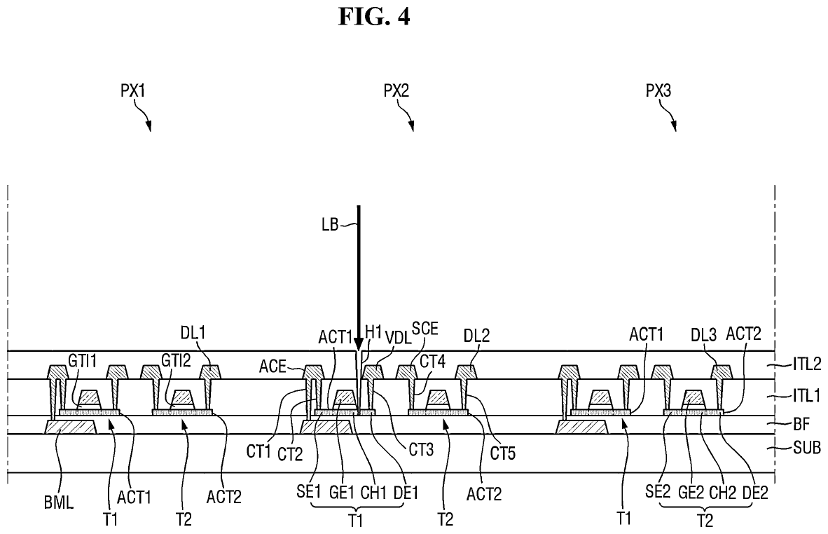

FIGS. 4 through 9 are cross-sectional views for explaining a method of fabricating a display device according to one or more embodiments.

First, as illustrated in FIG. 4, a substrate SUB on which a buffer layer BF, a first interlayer insulating layer ITL1, a second interlayer insulating layer ITL2, light-blocking layers BML, first gate-insulating layers GTI1, second gate-insulating layers GTI2, transistors T1, T2, and T3, anode connection electrodes ACE, data lines DL1, DL2, and DL3, source connection electrodes SCE, and a driving voltage line VDL are located may be prepared. Then, a first cutting hole H1 may be formed in a second cutting area CA2 to penetrate the second interlayer insulating layer ITL2, the first interlayer insulating layer ITL1, and a first active layer ACT1 of a second pixel PX2. For example, the first cutting hole H1 may be formed by a laser beam LB. In other words, as the laser beam LB is irradiated to a first cutting area CA1, the first active layer ACT1 of the second pixel PX2 may be divided in the first cutting area CA1 into a first part (e.g., a first source electrode SE1 and a first channel region CH1) and a second part (e.g., a first drain electrode DE1).

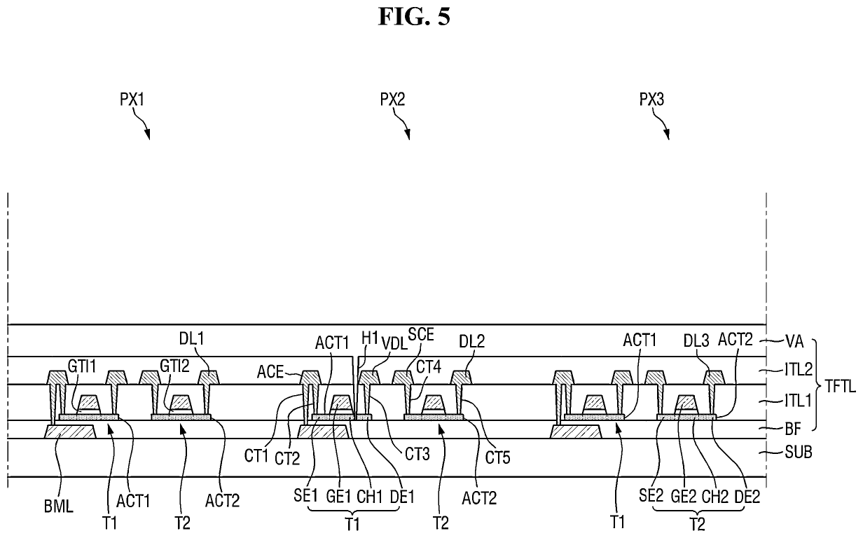

Next, as illustrated in FIG. 5, a planarization layer VA may be located on the second interlayer insulating layer ITL2. Here, the planarization layer VA may be further located in the first cutting hole H1. In other words, the first cutting hole H1 may be filled with the planarization layer VA.

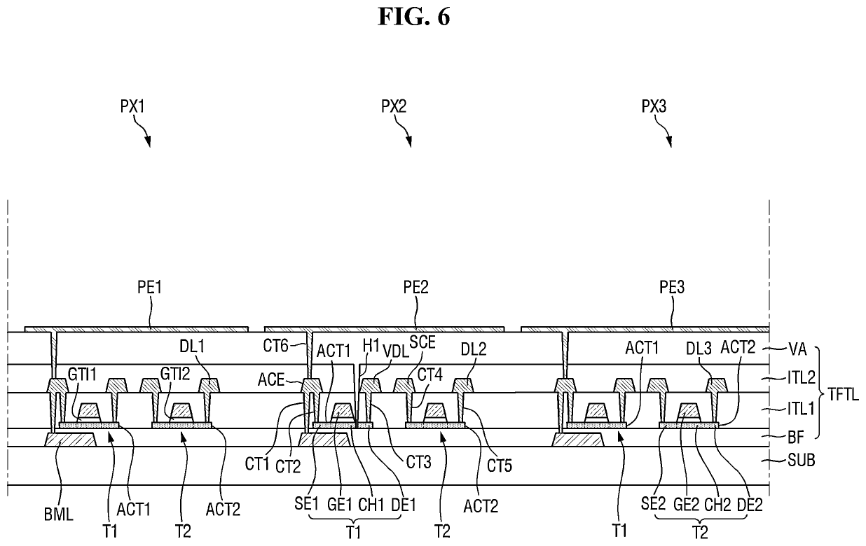

Next, as illustrated in FIG. 6, sixth contact holes CT6 may be formed to penetrate the planarization layer VA and the second interlayer insulating layer ITL2. Then, a first anode AE1, a second anode AE2, and a third anode AE3 may be located on the planarization layer VA. At this time, the first anode AE1 may be connected to the anode connection electrode ACE of a first pixel PX1 through the sixth contact hole CT6 of the first pixel PX1, the second anode AE2 may be connected to the anode connection electrode ACE of the second pixel PX2 through the sixth contact hole CT6 of the second pixel PX2, and the third anode AE3 may be connected to the anode connection electrode ACE of a third pixel PX3 through the sixth contact hole CT6 of the third pixel PX3.

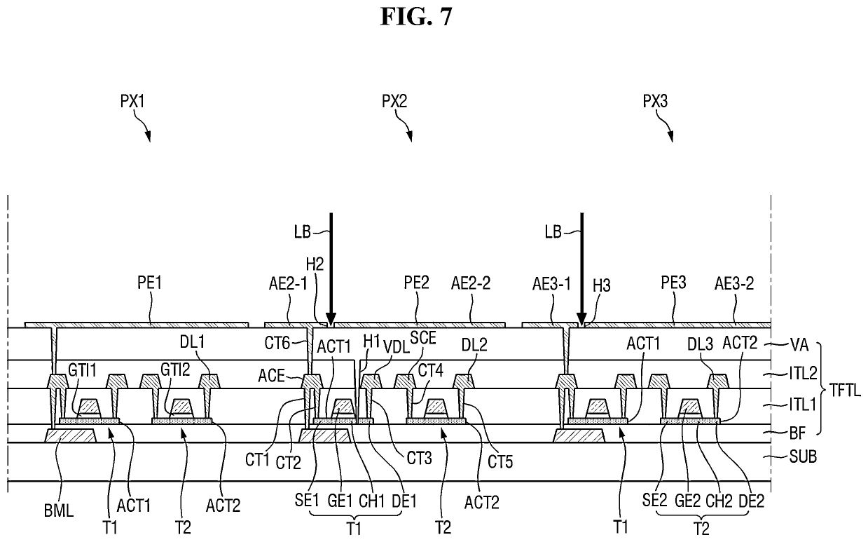

Next, as illustrated in FIG. 7, a second cutting hole H2 may be formed in a third cutting area CA3 to cut the second anode AE2. For example, the second cutting hole H2 may be formed by a laser beam LB. In other words, as the laser beam LB is irradiated to the third cutting area CA3, the second anode AE2 of the second pixel PX2 may be divided in the third cutting area CA3 into a first part AE2-1 (e.g., a first part connected to the second anode connection electrode ACE of the second pixel PX2 and not connected to a second light-emitting layer EL2) and a second part AE2-2 (e.g., a second part not connected to the second anode connection electrode ACE of the second pixel PX2 and connected to the second light-emitting layer EL2).

Next, as illustrated in FIG. 7, a third cutting hole H3 may be formed in a fourth cutting area CA4 to cut the third anode AE3. For example, the third cutting hole H3 may be formed by a laser beam LB. In other words, as the laser beam LB is irradiated to the fourth cutting area CA4, the third anode AE3 of the third pixel PX3 may be divided in the fourth cut area CA4 into a first part AE3-1 (e.g., a first part connected to the third anode connection electrode ACE of the third pixel PX3 and not connected to a third light-emitting layer EL3) and a second part AE3-2 (e.g., a second part not connected to the third anode connection electrode ACE of the third pixel PX3 and connected to the third light-emitting layer EL3).

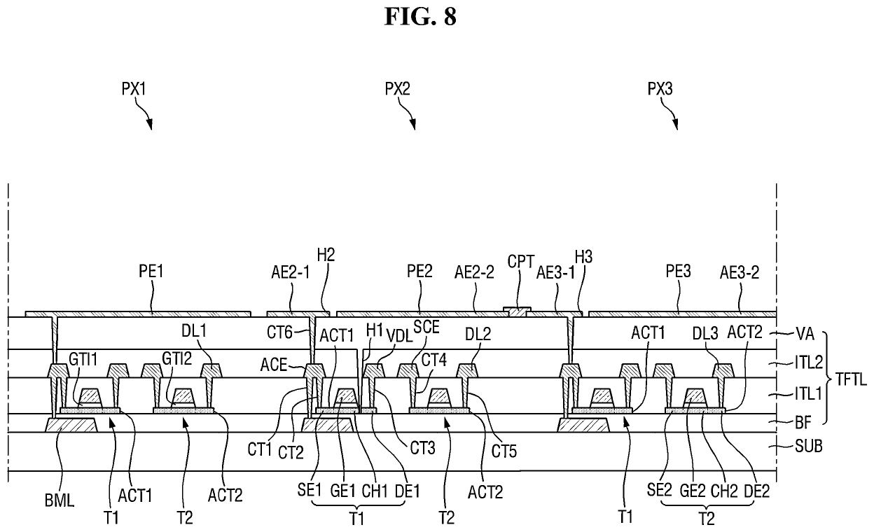

Next, as illustrated in FIG. 8, a connection pattern CPT may be located on the planarization layer VA to connect the second part AE2-2 of the second anode AE2 to the first part AE3-1 of the third anode AE3. For example, the connection pattern CPT may be made of conductive ink. The conductive ink may be applied on the second part AE2-2 of the second anode AE2 and the first part AE3-1 of the third anode AE3. In addition, the conductive ink may be applied between the second part AE2-2 of the second anode AE2 and the first part AE3-1 of the third anode AE3. Then, the conductive ink may be cured to form the connection pattern CPT described above.

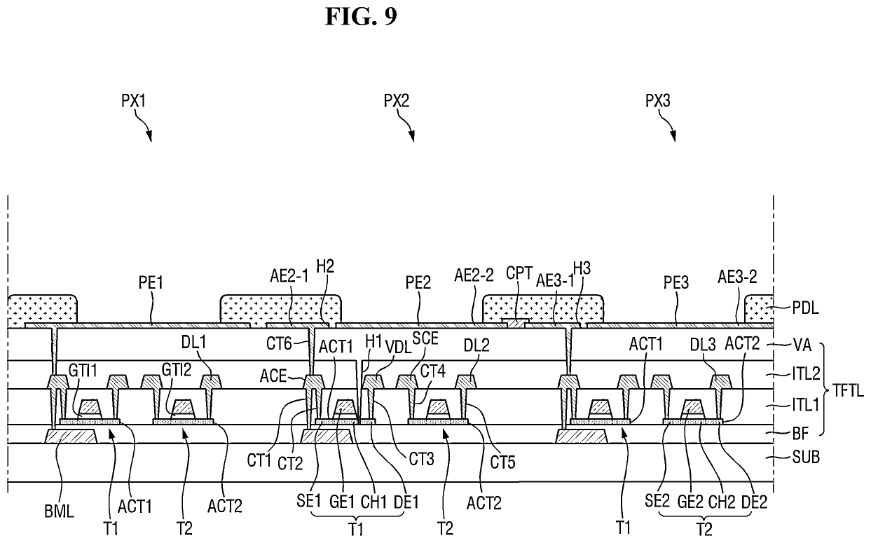

Next, as illustrated in FIG. 9, a pixel-defining layer PDL may be located on the first anode AE1, or the second anode AE2, on the third anode AE3, and on the connection pattern CPT. At this time, a portion of the pixel-defining layer PDL may be located in the second cutting hole H2 and the third cutting hole H3. In other words, each of the second cutting hole H2 and the third cutting hole H3 may be filled with the pixel-defining layer PDL.

Next, as illustrated in FIG. 3, the first light-emitting layer EL1, the second light-emitting layer EL2, and the third light-emitting layer EL3 may be located on the first anode AE1, the second anode AE2, and the third anode AE3, respectively. At this time, the first light-emitting layer EL1, the second light-emitting layer EL2, and the third light-emitting layer EL3 may be sequentially formed through different respective processes.

Next, a cathode CE may be located on the first light-emitting layer EL1, on the second light-emitting layer EL2, and on the third light-emitting layer EL3.

Then, an encapsulation layer ENC may be located on the cathode CE.

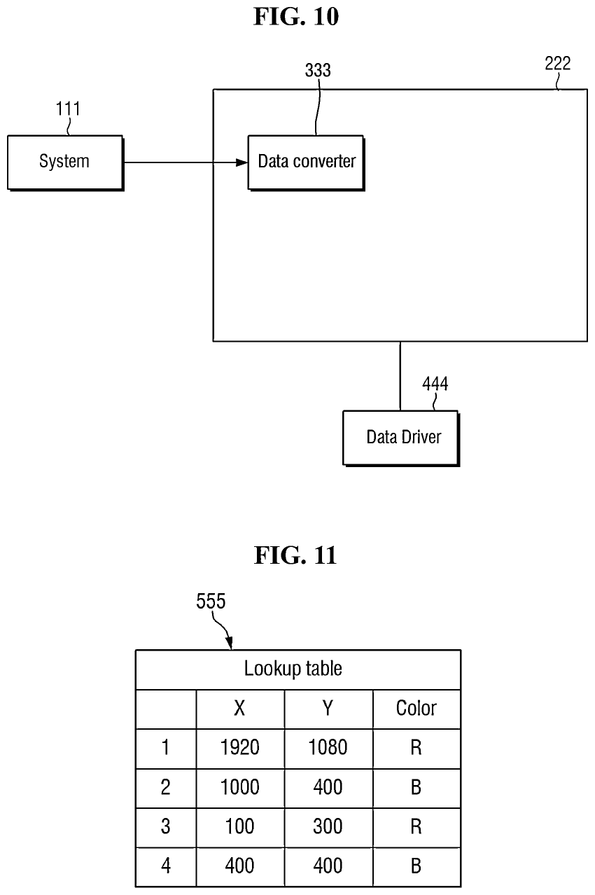

FIG. 10 is a block diagram of a driving circuit of a display device according to one or more embodiments.

The driving circuit of the display device may include a timing controller 222 and a data driver 444 as illustrated in FIG. 10.

The timing controller 222 may receive digital video data and timing signals from a system 111. The timing controller 222 may control the operation timing of the data driver 444 by generating a data control signal based on the timing signals, may control the operation timing of a gate driver by generating a gate control signal, and may control the operation timing of an emission control driver by generating an emission control signal. The timing controller 222 may supply the digital video data and the data control signal to the data driver 444.

In addition, the timing controller 222 may convert the digital video data from the system 111 based on repaired pixels and darkened pixels. To this end, the timing controller 222 may include a data converter 333. The data converter 333 may convert the digital video data from the system 111. For example, if a second pixel PX2 (e.g., a green pixel) is repaired as described above, the data converter 333 may convert digital video data (hereinafter, referred to as third digital video data) corresponding to a darkened third pixel PX3 (e.g., a blue pixel) adjacent to the second pixel PX2 into digital video data (hereinafter, referred to as second digital video data) corresponding to the second pixel PX2, and may provide the second digital video data to the data driver 444. Then, the data driver 444 converts the second digital video data into an analog data voltage D2 (hereinafter, referred to as a second data voltage), and transmits the second data voltage D2 to a third data line DL3 connected to the third pixel PX3. Then, a pixel circuit of the third pixel PX3 may generate a driving current corresponding to the second data voltage D2, and may supply the driving current to a second light-emitting element ED2 of the second pixel PX2. Therefore, the repaired second pixel PX2 can provide light at a luminance level corresponding to the magnitude of the original second data voltage D2.

The data driver 444 may convert digital video data from the timing controller 222 into analog data voltages D1, D2, and D3, and may supply the data voltages D1, D2, and D3 to data lines through fan-out lines. Scan signals of the gate driver may select pixels to which the data voltages are to be supplied, and the selected pixels may receive the data voltages through the data lines. For example, the gate driver may supply a first scan signal SC to a gate electrode of a switching transistor T2, and a second scan signal SS to a gate electrode of an initialization transistor T3.

FIG. 11 shows a lookup table 555 included in the data converter 444 of FIG. 10.

The data converter 333 may include the lookup table 555 as illustrated in FIG. 11. For example, the data converter 333 may include the lookup table 555 having coordinate information about coordinates of a repaired pixel (e.g., the second pixel PX2), and coordinates of a darkened pixel (e.g., the third pixel PX3) that is connected to the repaired pixel.

The data converter 333 may convert first digital video data (e.g., digital video data corresponding to the darkened pixel) into second digital video data (e.g., digital video data corresponding to the repaired pixel) based on the coordinates of the repaired pixel and the coordinates of the darkened pixel stored in the lookup table 555.

X and Y in the lookup table 555 may represent coordinates of a repaired pixel (e.g., a green pixel). In addition, ‘color’ in the lookup table 555 may represent a pixel (or coordinates of a pixel) connected to a light-emitting element of the repaired pixel. For example, row 1 of the lookup table 555 shows 1920 as an X coordinate, 1080 as a Y coordinate, and R as a color. This may mean that a light-emitting element of a pixel (e.g., a repaired green pixel) located at the X coordinate of 1920 and the Y coordinate of 1080 is connected to a pixel circuit of a red pixel adjacent to the pixel. Here, the red pixel in row 1 is a darkened pixel. For another example, row 2 of the lookup table 555 shows 1000 as the X coordinate, 400 as the Y coordinate, and B as the color. This may mean that a light-emitting element of a pixel (e.g., a repaired green pixel) located at the X coordinate of 1000 and the Y coordinate of 400 is connected to a pixel circuit of a blue pixel adjacent to the pixel. Here, the blue pixel in row 2 is a darkened pixel.

The data converter 333 may detect digital video data corresponding to a darkened pixel, and may convert the detected digital video data into digital video data corresponding to a repaired pixel based on the lookup table 555 described above. For example, the data converter 333 may convert red digital video data corresponding to the darkened red pixel in row 1 into green digital video data (e.g., green digital video data corresponding to the repaired pixel in row 1 of the lookup table 555). For another example, the data converter 333 may convert blue digital video data corresponding to the darkened blue pixel in row 2 into green digital video data (e.g., green digital video data corresponding to the repaired pixel in row 2 of the lookup table 555). The digital video data converted by the data converter 333 may be supplied to the data driver 444.

According to one or more embodiments, if a green pixel, which contributes most to luminance in a unit pixel including a red pixel, the green pixel, and a blue pixel, is defective, then a light-emitting element of the green pixel is driven using a driving current from a pixel circuit of another normal pixel adjacent to the green pixel. Therefore, a defect rate of the display device can be reduced or minimized.

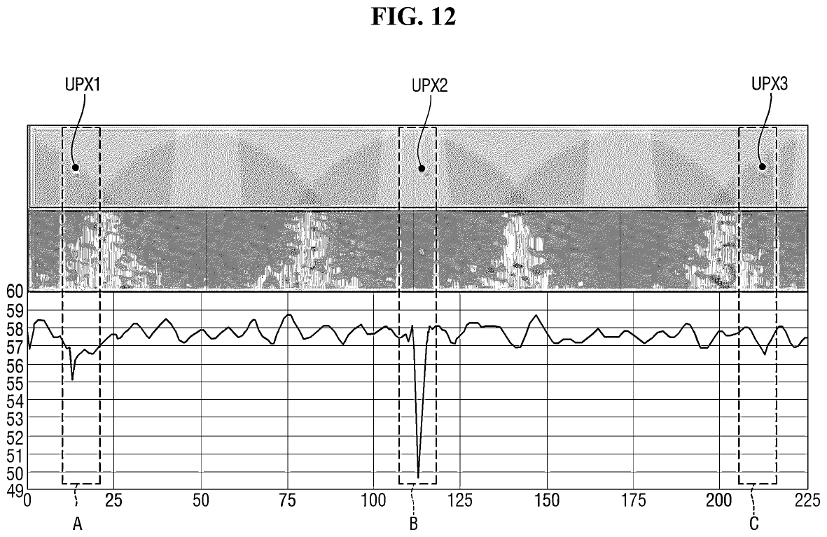

FIG. 12 is a diagram for explaining luminance contributions of a red pixel, a green pixel, and a blue pixel of a display device.

In FIG. 12, the X-axis represents the location (e.g., coordinates) of a pixel, and the Y-axis represents luminance.

A first unit pixel, a second unit pixel, and a third unit pixel may each be a unit pixel including a red pixel, a green pixel, and a blue pixel.

The first unit pixel includes a red pixel, a green pixel, and a blue pixel. Here, the luminance of a first area A is the luminance of the first unit pixel if only the red pixel among the red, green, and blue pixels of the first unit pixel is darkened.

The second unit pixel includes a red pixel, a green pixel, and a blue pixel. Here, the luminance of a second area B is the luminance of the second unit pixel if only the green pixel among the red, green, and blue pixels of the second unit pixel is darkened.

The third unit pixel includes a red pixel, a green pixel, and a blue pixel. Here, the luminance of a third area C is the luminance of the third unit pixel if only the blue pixel among the red, green, and blue pixels of the third unit pixel is darkened.

As illustrated in FIG. 12, it can be seen that the luminance of a unit pixel is lowest if a green pixel is darkened. Therefore, if the green pixel is defective, a light-emitting element of the green pixel is driven using a driving current from a pixel circuit of another adjacent pixel (e.g., a red pixel or a blue pixel). Accordingly, a defect rate of the display device can be reduced or minimized.

In a display device according to the present disclosure, a defect rate can be reduced or minimized.

However, the effects of the present disclosure are not restricted to the one set forth herein. The above and other effects of the present disclosure will become more apparent to one of daily skill in the art to which the present disclosure pertains by referencing the claims.

It will be able to be understood by one of ordinary skill in the art to which the present disclosure belongs that the present disclosure may be implemented in other forms without changing the technical spirit or essential features of the present disclosure. Therefore, it is to be understood that the exemplary embodiments described above are illustrative rather than being restrictive in all aspects. It is to be understood that the scope of the present disclosure are defined by the claims rather than the detailed description described above and all modifications and alterations derived from the claims and their functional equivalents fall within the scope of the present disclosure.

What is claimed is:

1. A display device comprising:
a first pixel comprising a first pixel circuit and a first light-emitting element, the first pixel circuit being separated from a portion of the first light-emitting element; and
a second pixel comprising a second pixel circuit and a second light-emitting element, the second pixel circuit being separated from a portion of the second light-emitting element, and being connected to a portion of the first light-emitting element.

2. The display device of claim 1, wherein a first anode of the first light-emitting element comprises a first part and a second part separated from each other by a first cutting hole penetrating the first anode, and
wherein a second anode of the second light-emitting element comprises a first part and a second part separated from each other by a second cutting hole penetrating the second anode.

3. The display device of claim 2, wherein the first part of the first anode is connected to a first driving transistor of the first pixel circuit, and
wherein the first part of the second anode is connected to a second driving transistor of the second pixel circuit.

4. The display device of claim 3, wherein the second part of the first anode is connected to a first light-emitting layer of the first light-emitting element and the first part of the second anode.

5. The display device of claim 4, further comprising a connection pattern connecting the second part of the first anode to the first part of the second anode.

6. The display device of claim 5, wherein the connection pattern is at a same layer as the first anode and the second anode.

7. The display device of claim 5, wherein the connection pattern comprises conductive ink.

8. The display device of claim 7, wherein the conductive ink comprises Ag ink.

9. The display device of claim 5, further comprising a pixel-defining layer above the connection pattern to overlap the connection pattern, and defining a pixel area of the first pixel and a pixel area of the second pixel.

10. The display device of claim 3, wherein a gate electrode and a drain electrode of the first driving transistor of the first pixel circuit are separated from the first pixel circuit, and
wherein a source electrode of the first driving transistor is separated from the first anode of the first light-emitting element.

11. The display device of claim 10, wherein the first driving transistor of the first pixel circuit comprises an active layer comprising the drain electrode and the source electrode, and comprising a first part and a second part separated from each other by a third cutting hole penetrating the active layer.

12. The display device of claim 11, wherein the first part of the active layer comprises the source electrode of the first driving transistor and a channel region of the first driving transistor, and
wherein the second part of the active layer comprises the drain electrode of the first driving transistor.

13. The display device of claim 12, further comprising an insulating layer above the first driving transistor, wherein the third cutting hole penetrates the insulating layer.

14. The display device of claim 1, further comprising:
a first data line connected to the first pixel; and
a second data line connected to the second pixel.

15. The display device of claim 14, further comprising a data driver for transmitting a data voltage, which corresponds to the first pixel, to the second data line in a data input period of the first pixel.

16. The display device of claim 15, further comprising a data converter for converting first digital video data corresponding to the second pixel into second digital video data corresponding to the first pixel, and for providing the second digital video data to the data driver,
wherein the data driver is configured to generate the data voltage corresponding to the first pixel based on the second digital video data.

17. The display device of claim 16, wherein the data converter comprises a lookup table having coordinate information of coordinates of the first pixel and coordinates of the second pixel.

18. The display device of claim 17, wherein the data converter is configured to convert the first digital video data into the second digital video data based on the coordinates of the first pixel and the coordinates of the second pixel.

19. The display device of claim 1, wherein the first light-emitting element comprises a green light-emitting layer, and
wherein the second light-emitting element comprises a red light-emitting layer or a blue light-emitting layer.

20. The display device of claim 1, wherein the second pixel is adjacent to the first pixel.

21. A method of fabricating a display device, the method comprising:
preparing a substrate having thereabove a first driving transistor of a first pixel, a second driving transistor of a second pixel, and a first insulating layer above the first and second driving transistors;
separating a first gate electrode of the first driving transistor from a pixel circuit of the first pixel;
dividing an active layer of the first driving transistor into a first part comprising a first channel region and a first source electrode, and a second part comprising a first drain electrode, by forming a first cutting hole penetrating the first insulating layer and the active layer of the first driving transistor;
forming a second insulating layer above the first insulating layer;
forming, above the second insulating layer, a first anode connected to the first source electrode, and a second anode connected to a second source electrode;
dividing the first anode into a first part connected to the first driving transistor, and a second part to be connected to a first light-emitting layer of the first pixel, and dividing the second anode into a first part connected to the second driving transistor of the second pixel, and a second part, by forming a second cutting hole and a third cutting hole penetrating the first anode and the second anode, respectively;
connecting the second part of the first anode to the first part of the second anode;
forming a pixel-defining layer above the first anode and the second anode;
forming the first light-emitting layer above the first anode;
forming a second light-emitting layer above the second anode; and
forming a cathode above the first light-emitting layer and the second light-emitting layer.

22. The method of claim 21, wherein the first light-emitting layer comprises a green light-emitting layer, and
wherein the second light-emitting layer comprises a red light-emitting layer or a blue light-emitting layer.
